(19) United States
(12) Patent Application Publication
(10) Pub. No.: US 2012/0226458 A1
(43) Pub. Date: Sep. 6, 2012

(54) SFP - DIAGNOSTIC

(75) Inventors: Renaud LAVOIE, Laval (CA); Éric DUDEMAINE, Crabtree (CA)

(73) Assignee: EMBRIONIX DESIGN INC., Laval (CA)

(21) Appl. No.: 13/040,681

(22) Filed: Mar. 4, 2011

(51) Int. Cl. G06F 19/00; G01R 23/00

(52) U.S. Cl. 702/69; 702/66; 702/75

(57) ABSTRACT

A small form-factor pluggable (SFP) unit having signal diagnostic capabilities comprises one or more diagnostic measurement points. At least one of the one or more diagnostic measurement points provides a signal diagnostic measurement for diagnostic of the SFP unit.

The present disclosure relates to small form factor pluggable units, and more particularly to a small form factor pluggable unit having signal diagnostic capabilities.

### BACKGROUND

Small Form-factor Pluggable (SFP) units are standardized units adapted to be inserted within a chassis. A suite of specifications, produced by the SFF (Small Form Factor) Committee, describe the size of the SFP unit, so as to ensure that all SFP compliant units may be inserted smoothly within one same chassis, i.e. inside cages, ganged cages, superposed cages and belly-to-belly cage. Specifications for SFP units are available at http://www.sffcommittee.com/ie/index.html.

Specification no SFF-8472 Rev 11.0, entitled “Diagnostic Monitoring Interface for Optical Transceivers”, dated Sep. 14, 2010, was produced by the SFF Committee. The specification defines a memory map with a digital diagnostic monitoring interface for optical transceivers that allows pseudo real time access to device operating parameters. It also defines options to previously defined two-wire interface ID memory map that accommodate new transceiver types that were not considered in earlier SFP Multi-Source Agreement (MSA) or Gigabit Interface Converter (GBIC) documents. The SFF Committee also produced specification no SFF-8431 Rev. 4.1, “Enhanced Small Form Factor Pluggable Module SFP+”, dated Jul. 6, 2010. This document defines, inter alia, high speed electrical interface specifications for 10 Gigabit per second SFP+ modules and hosts. The term “SFP+” designates an evolution of SFP specifications.

However, SFF-8472 and SFF-8431 do not address measurements of characteristics of electrical signals received at the SFP unit, or within the SFP unit. SFF-8431 only describes a test methodology for optical signals, in a context requiring use of test equipment that is external to a SFP unit under test.

### BRIEF DESCRIPTION OF THE DRAWINGS

In the appended drawings, provided for exemplary purposes only, similar references denote like parts:

FIG. 1 is a top view of a SFP unit;

FIG. 2 is a side elevation view of the SFP unit of FIG. 1;

FIG. 3 is a front elevation view of the SFP unit of FIG. 1;

FIG. 4 is back elevation view of the SFP unit of FIG. 1;

FIG. 5 is a bottom view of the SFP unit of FIG. 1;

FIG. 6 is a simplified, exemplary block diagram of a SFP unit having signal diagnostic capabilities, according to an embodiment;

FIG. 7 is a simplified, exemplary block diagram of a SFP unit having signal diagnostic capabilities, according to another embodiment; and

FIG. 8 is an exemplary eye diagram representing a signal at a measurement point of the SFP unit of FIGS. 6 and 7.

### DETAILED DESCRIPTION

The foregoing and other features of the present will become more apparent upon reading of the following non-restrictive description of examples of implementation thereof, given by way of illustration only with reference to the accompanying drawings. Like numerals represent like features on the various drawings.

The present disclosure relates to a small form-factor pluggable (SFP) unit having signal diagnostic capabilities. The expression ‘signal diagnostic’ is used throughout the present disclosure and claims, and is meant to be interpreted to encompass signal monitoring, signal measurement, and diagnostic of signal based on measured signal characteristics.

The SFP unit comprises a housing having a front panel, a back panel, a top, a bottom and two sides, and may be fully-compliant or partially compliant with standardized SFP dimensions, such as SFP, XFP (10 Gigabit SFP), Xenpak, or any other standardized small form factor pluggable unit.

In the context of the present SFP unit, the following terminology is used: “SFP” designates a Small Form Factor Pluggable Unit corresponding to SFP, SFP+, XFP or any other known standards related to small form factor pluggable units.

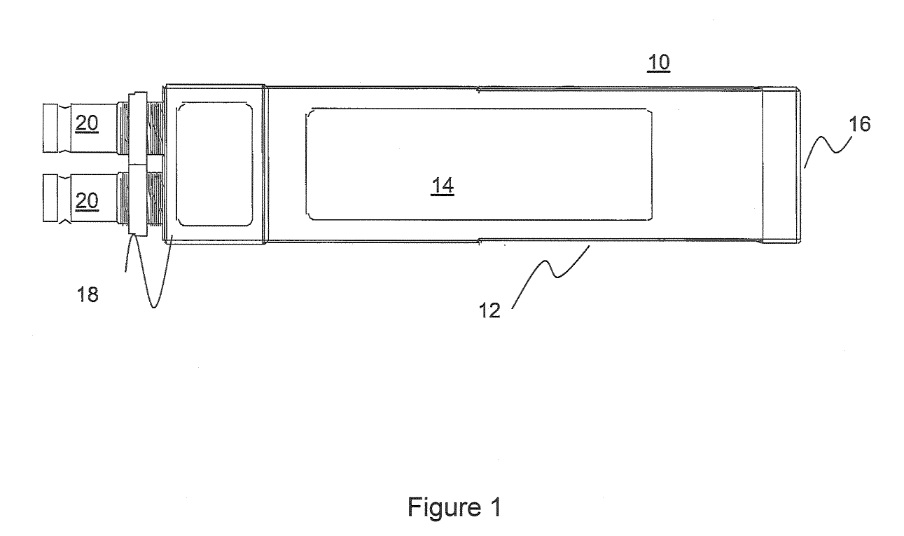

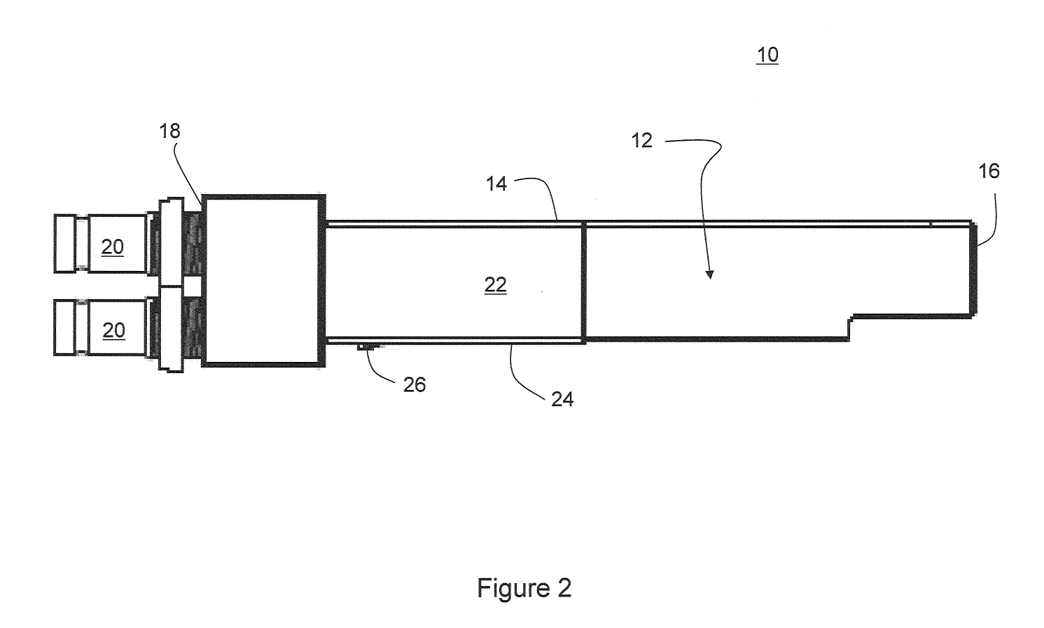

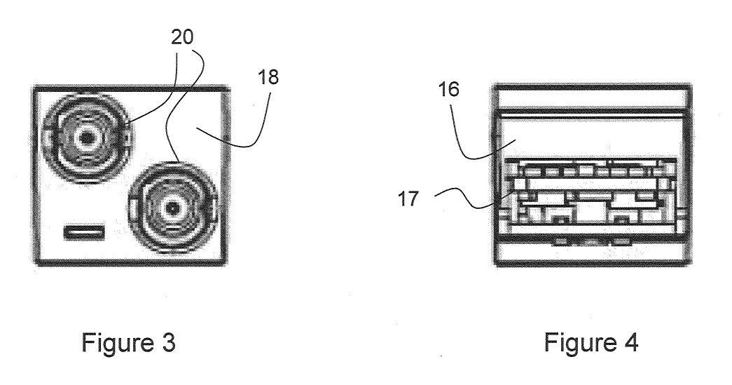

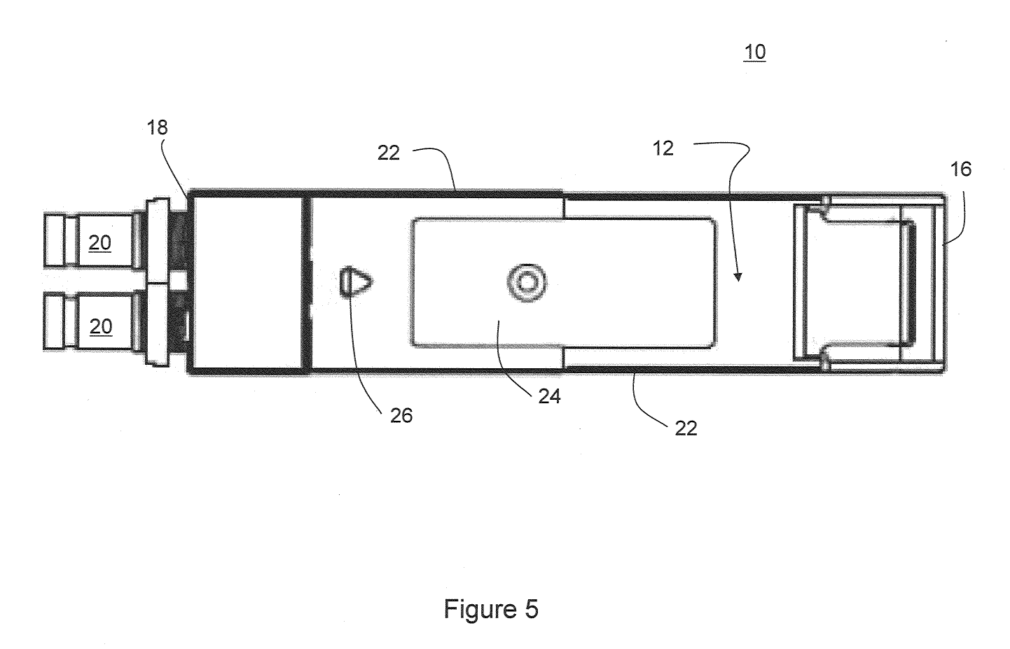

Reference is now made concurrently to FIGS. 1-5, which are, respectively, a top view, a side elevation view, a front elevation view, a back elevation view and a bottom view of a SFP unit 10. The SFP unit 10 comprises a housing 12. The housing defines a top 14, a bottom 24, and two sides 22. The housing 12 is at least partially of dimensions in compliance with the SFP, SFP+ and/or XFP specifications or having functional dimensions based on the SFP or SFP+ specifications.

The SFP unit 10 further comprises a back panel 16 affixed to the housing 12. The back panel 16 may comprise one or more connectors 17, for example electrical or optical. In an example, the back panel comprises a connector suitable to connect the SFP unit to a backplane of a chassis (not shown for clarity purposes), as known to those skilled in the art.

The SFP unit 10 further comprises a front panel 18 affixed to the housing 12. The front panel may comprise one or more connectors, for example co-axial connectors 20 adapted to send and/or receive radio frequency (RF) signals, for connecting the SFP unit to external devices. The SFP unit 10 may further comprise an engagement mechanism such as for example a latch 26 as shown in a resting position on the bottom 24, for maintaining the SFP unit 10 in place within a chassis. Although not shown, the SFP unit further comprises at least one receiver, at least one transmitter and/or at least one transceiver. The SFP unit 10 may alternately comprise dual receivers and/or dual transmitters. Each connector of the SFP unit is directly connected to a transmitter, a transceiver or a transceiver.

Examples of connectors in the context of the present disclosure comprise electric and optic connectors such as: 8P8C connectors, Universal Serial Bus connectors, Radio Frequency (RF) connectors, Audio connectors, Video connectors, all types of coaxial cable connectors and all types of optic fiber connectors.

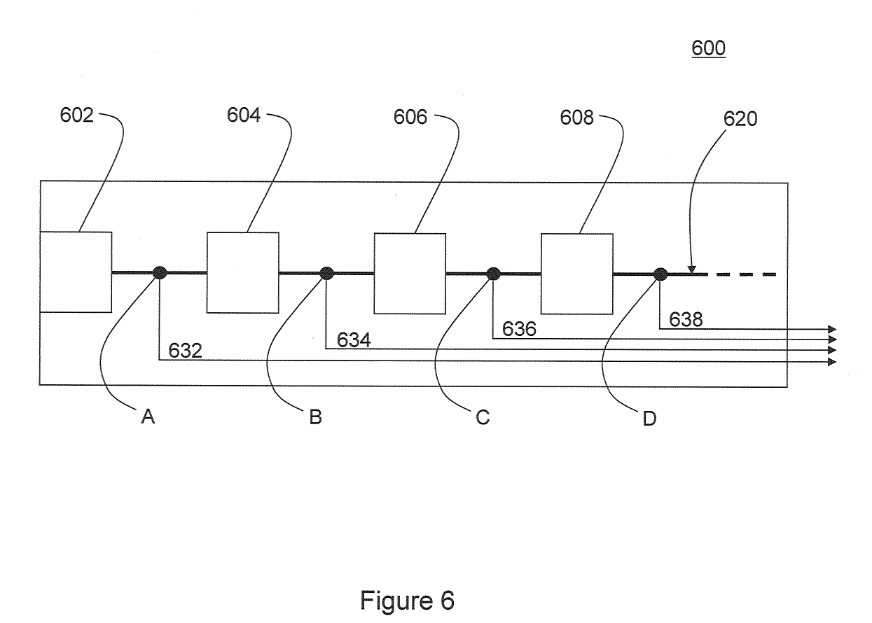

Reference is now made to FIG. 6, which shows a simplified, exemplary block diagram of a SFP unit 600 having signal diagnostic capabilities, according to an embodiment. The SFP unit 600 may comprise one or a series of functional blocks. Examples of such functional blocks may comprise an input 602 connected to one of the connectors 20 (visible on previous Figures). The input 602 may consist of a transmitter, a receiver or a transceiver. The functional blocks further comprise a DC restore (WHAT DOES DC STANDS FOR? it is part of the equalizer, to rebalance the DC level, because the NRZI is unbalanced)(DC) block 604, an equalizer 606 and a reclocker unit (CRU). 608. In the event that the connector is an optic connector, the equalizer 606 could be replaced by a transimpedance amplifier, followed by a limiting amplifier, and a laser driver+laser replace the cable driver. Other example of functional blocks include a cable driver, a crosspoint switch or a crossbar, a Field Programmable Gate Array and a dedicated Application-Specific Integrated Circuit. Various functional blocks could be incorporated within the SFP unit 10, and the depicted functional blocks 602-608 are shown for exemplary purposes only. Furthermore, although shown as functional blocks, those skilled in the art will recognize that the functional blocks are used for simplifying graphical representation of the possible components within the SFP unit 10, as such functional blocks are realized by means of hardware and/or software.

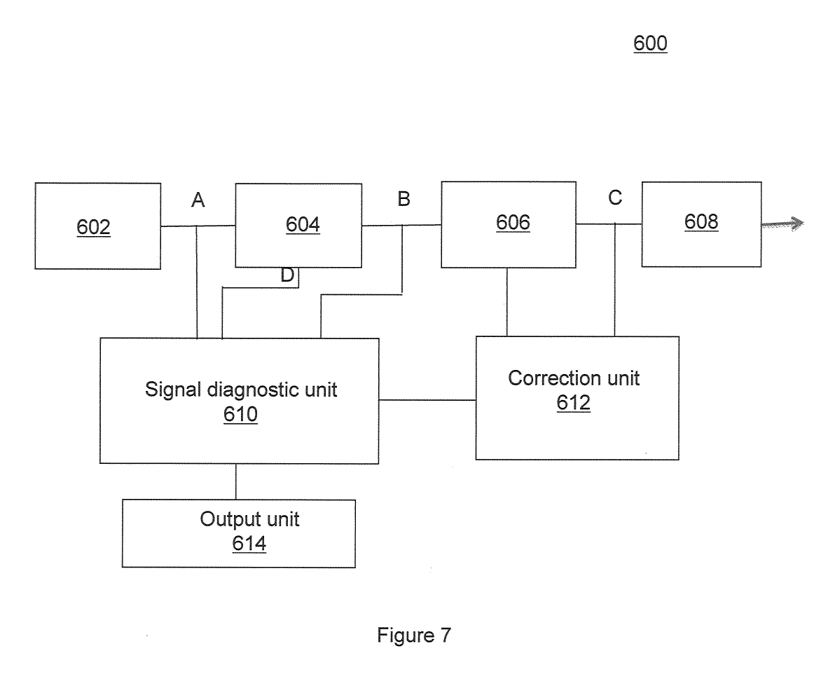

Diagnostic measurement points A, B, C, D illustrate exemplary locations on a signal path 620 within the SFP unit, located after the input module 602, where signal diagnostic measurements may be obtained. As shown on FIG. 6, the signal diagnostic measurements may be performed between two functional blocks, or between several functional blocks. Alternately, the signal diagnostic measurements may be performed directly within the functional block, as shown on FIG. 7.

Signal diagnostic measurements from the measurements points A, B, C, D, may be measured by a measuring unit such as an electric, optic or electronic components or group thereof, not shown for clarity purposes. Signal diagnostic measurements at diagnostic measurement points A, B, C and D may be directly outputted from the SFP unit 600 in the form of measurement signals on lines 632, 634, 636 and 638. Some or all of the lines 632, 634, 636 and 638 may be connected on one or more connectors 17 as shown on FIG. 4.

Reference is now made to FIG. 7, which shows a simplified, exemplary block diagram of a SFP unit 600 having additional signal diagnostic capabilities, according to another embodiment. The SFP unit of FIG. 7 differs from the SFP unit of FIG. 6 in that it further comprises a signal diagnostic unit 610, a correction unit 612 and an output unit 614. In this particular embodiment, the SFP unit 600 is thus adapted to perform signal diagnostic measurements at one or several diagnostic measurement points shown as A, B, C and D, but is further adapted for diagnosticating the signal diagnostic measurements. The signal diagnostic unit 610 is further adapted for determining whether a correction is required, and determine the required correction. The required correction is then provided to the correction unit 612 for performing a corresponding correction in the functional block 606. The SFP unit 600 may further validate that the applied correction by the functional block 606 has been sufficient, by performing a measurement on the signal path at the measurement point C, which is after the functional block 606, so that the correction unit 612 may confirm that the applied correction was successful to the signal diagnostic unit 610. Additionally, the signal diagnostic unit 610 may provide the signal diagnostic measurements from the measurement points A, B, C and D, and/or the signal diagnostic results obtained from the signal diagnostic unit 610 and/or the applied correction to an output unit 614, which is adapted for outputting the information to an exterior device used for troubleshooting the SFP unit 600 or the signal(s) received by the SFP unit 600.

In an exemplary implementation of the present SFP unit, the signal diagnostic unit 610 receives a signal diagnostic measurement from the diagnostic point A, i.e. between an equalizer 602 and a reclocker 604, indicating that amplitude of the signal at diagnostic point A is weak. The signal diagnostic unit 601 determines a required correction for the correction unit 612, indicating that the correction unit 612 must boost the signal.

In another exemplary implementation, the signal diagnostic unit 610 receives a signal measurement from the diagnostic point B, located before a reclocker 606. The signal diagnostic unit 610 determines that the signal at detection point B is closed in time, i.e. suffers from a lot of jitter, and that the amplitude is low. The signal diagnostic unit 610 instructs the correction unit 612 to retime the signal with the assistance of the reclocker 606, and amplifies the output power of the signal. By performing signal diagnosis of the signal along the signal path in the SFP unit, and correcting the signal based on the diagnosed information, it is possible to have an output signal at the crosspoint or crossbar 608 with better quality than at the entry of the SFP unit.

Although FIG. 7 depicts only one correction unit 612, the present SFP unit 600 is not limited to such a configuration. A single correction unit 612 is shown on FIG. 7 so as to depict the possibility of determining required correction, and performing the required correction in the functional block 606, but the present SFP unit 600 and signal diagnostic unit 610 may be adapted to receive several correction units 612, wherein each correction unit 612 may perform a correction to a specific aspect of the signal path 620, or alternately the correction unit 612 may control several functional blocks 602-608 so as to apply appropriate correction therein, based on the results obtained from the signal diagnostic unit 610.

Thus the present SFP unit 600 is not limited to receiving signal(s) from one or several connectors, but further performs signal diagnostic measurements at one or several diagnostic points of the signal path. Furthermore, the present SFP unit 600 may further use the signal diagnostic measurements to perform a signal diagnostic, and determine required correction. Also, the present SFP unit 600 may be adapted for correcting the signal based on the determined required correction.

As mechanical dimensions for SFP units are rather small, the present diagnostic measurement points A, B, C and D, signal diagnostic unit 610, correction unit 612 and output unit 614 may be implemented in dedicated hardware, made part of an integrated circuit, or comprise software components. Peut-on inclure XFP, et autre format de module pluggable? (Fait aux paragraphes 16 et 17)

The signal diagnostic measurements may comprise one or several types of signal measurements, such as for example: signal integrity, signal quality, signal strength, noise level, signal-to-noise ratio, distortion, jitter, bit rate, amplitude, wander, alignment jitter, timing jitter, (for example relative to an external signal, to a signal obtained at another measurement point, or to a reference clock), frequency, and the like. Information elements equivalent to those of typical eye diagrams may also be obtained for the signal diagnostic measurements obtained on the various diagnostic measurement points.

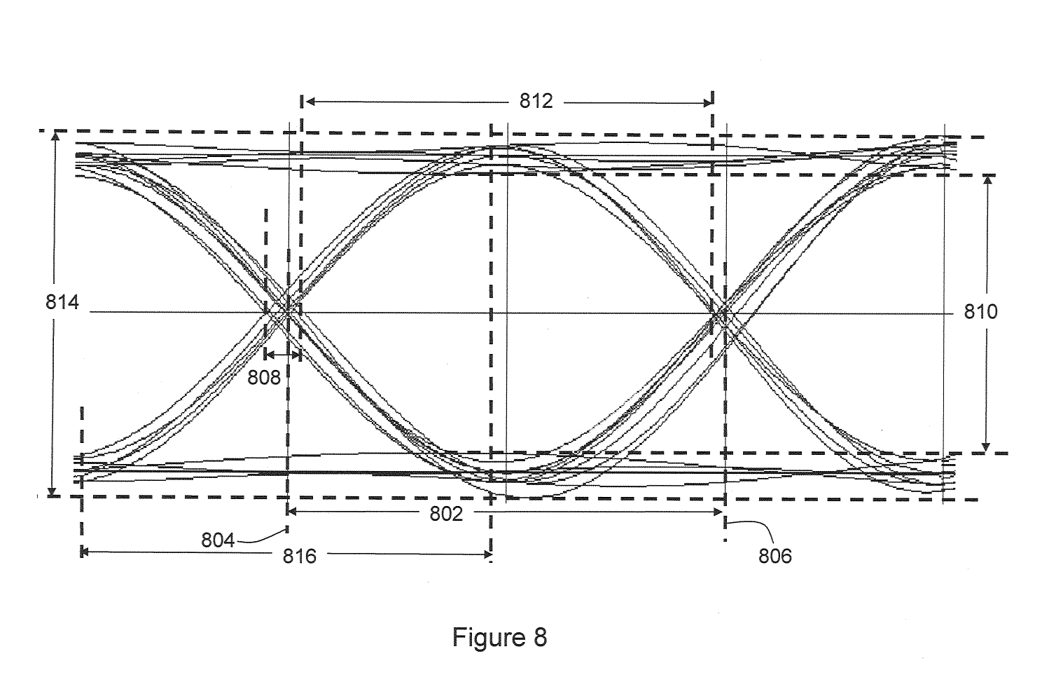

FIG. 8 shows an exemplary eye diagram representing a signal at a diagnostic measurement point of the present SFP unit. As known to those skilled in the art, an eye diagram 800 for a signal may be obtained, for example on a display of an oscilloscope, by inputting the signal to a vertical input of the oscilloscope, using a data rate as a trigger for a horizontal sweep of the oscilloscope.

Diagnosticating of signal diagnostic measurement from the SFP unit 600 may provide similar information elements as those obtainable using an oscilloscope. As shown in FIG. 8, exemplary information elements obtainable by diagnosticating the signal diagnostic measurements may comprise a data period (or clock rate) 802 defined by ideal transition points 804, 806 between data symbols, and maximum (or peak-to-peak) jitter 808 around transition points 804, 806 (only shown around point 804). Other exemplary information elements comprise vertical eye opening 810, horizontal eye opening 812, maximum signal amplitude 814, signal rise duration 816, overshoot and undershoot at the edges of the signals and like signal characteristics. Other information elements may be obtained from further diagnosticating, for example a figure of merit of a measurement signal related to its signal to noise ratio (SNR), root-mean square (RMS) jitter, timing jitter and wander, in which wander comprises low frequency components of the jitter whereby points 804, 806 tend to shift to earlier or later points in time, relative to their positions on FIG. 8.

As can be appreciated by those skilled in the art, the present SFP unit with signal diagnostic capabilities adjusts the eye opening of the signal, based on the quality of the signal along the signal path. providing an output signal with better signal quality than the signal received.

Although the present SFP unit has been described in the foregoing description by way of illustrative embodiments thereof, these embodiments can be modified at will, within the scope of the appended claims without departing from the spirit and nature of the present SFP unit.

What is claimed is:

1. A small form-factor pluggable (SFP) unit comprising:
at least one diagnostic measurement point along a signal path in the SFP unit for performing signal diagnostic measurement of a signal.

2. The SFP unit of claim 1, further comprising:
a signal diagnostic unit for receiving the signal diagnostic measurement from the diagnostic measurement point.

3. The SFP unit of claim 2, wherein the signal diagnostic unit diagnosticates the signal diagnostic measurement and provides therefore an element selected from the group consisting of an amplitude, a jitter, a wander, an alignment, a frequency and a bit rate.

4. The SFP unit of claim 2, wherein the signal diagnostic unit is adapted for determining a required correction on the signal, and the SFP unit further comprises a correction unit for performing a correction based on the required correction received from the signal diagnostic unit.

5. The SFP unit of claim 1, further comprising an electrical connector for receiving the signal.

6. The SFP unit of claim 1, further comprising an optic connector for receiving the signal.

7. The SFP unit of claim 1, wherein the at least one diagnostic measurement point is located between two functional blocks of the SFP unit.

8. The SFP unit of claim 1, wherein the at least one diagnostic measurement point is located within a functional block of the SFP unit.

9. The SFP unit of claim 2, comprising a plurality of diagnostic measurement points, and the signal diagnostic unit is adapted for performing a diagnostic of the signal based on the signal diagnostic measurements performed at the diagnostic measurement points.

10. The SFP unit of claim 4, wherein one of the diagnostic measurement point is located after the application of the required correction by the correction unit.

11. The SFP unit of claim 4, wherein the SFP unit further comprises a plurality of correction units.
